(19) United States
(12) Patent Application Publication
(10) Pub. No.: US 2026/0112880 A1
(43) Pub. Date: Apr. 23, 2026

(54) SWITCHING SPEED CONTROL BASED ON OVERSTRESS SIGNAL

(71) Applicant: Infineon Technologies AG, Neubiberg (DE)

(72) Inventors: Davide Dal Bianco, Schio (VI) (IT); Alexander Schade, Unterhaching (IT); Maurizio Galvano, Padova (IT)

(21) Appl. No.: 18/921,624

(22) Filed: Oct. 21, 2024

(51) Int. Cl. H02H 3/20; H02H 1/00

(52) U.S. Cl. CPC H02H 3/20; H02H 1/0007

(57) ABSTRACT

A circuit includes a device stress detector, buffer circuitry, and a switching speed controller. The device stress detector is configured to generate a device stress signal indicating an electrical characteristic at a switching element of power converter circuitry while driver circuitry controls the switching element at a switching speed. The buffer circuitry is configured to generate, based on the device stress signal, an overstress signal indicating whether the electrical characteristic at the switching element satisfies a threshold value. The switching speed controller is configured to generate, based on the overstress signal, a switching speed signal indicating a change to the switching speed and output the switching speed signal to the driver circuitry. The driver circuitry is configured to control, based on the switching speed signal, the switching element at a modified switching speed.

### TECHNICAL FIELD

This disclosure relates to circuits and techniques for controlling a switching element of power converter circuitry.

### BACKGROUND

Driver circuitry controls switching elements of power converter circuitry using a pulse modulated signal. For example, driver circuitry may control a switch of a Buck converter using a pulse-width modulated (PWM) signal.

### SUMMARY

In general, this disclosure is directed to techniques for adjusting a switching speed for controlling a switching element of power converter circuitry based on a device stress signal. For example, a circuit may generate a device stress signal indicating an electrical characteristic (e.g., a voltage or current) at the switching element while controlling the switching element at a switching speed. In this example, the circuit may generate a switching speed signal indicating a change (e.g., increase or decrease) to the switching speed based on an overstress signal. In this way, the circuit may adjust the switching speed in order to maximize a conversion efficiency (e.g., maximize a switching speed) on operating condition(s) while helping to ensure that electrical characteristics are below thresholds (e.g., reducing or avoiding voltage/current overstress). Maximizing conversion efficiency while helping to ensure that electrical characteristics are below thresholds may reduce a power loss in the power converter circuitry while helping to ensure reliability of the power converter circuitry (e.g., minimize failure of the switching element).

In some examples, the disclosure describes a circuit comprising a device stress detector, buffer circuitry, and a switching speed controller. The device stress detector is configured to generate a device stress signal indicating an electrical characteristic at a switching element of power converter circuitry while driver circuitry controls the switching element at a switching speed. The buffer circuitry is configured to generate, based on the device stress signal, an overstress signal indicating whether the electrical characteristic at the switching element satisfies a threshold value. The switching speed controller is configured to generate, based on the overstress signal, a switching speed signal indicating a change to the switching speed and output the switching speed signal to the driver circuitry. The driver circuitry is configured to control, based on the switching speed signal, the switching element at a modified switching speed.

In some examples, the disclosure describes a system comprising driver circuitry, a device stress detector, buffer circuitry, and a switching speed controller. The driver circuitry is configured to control a switching element of power converter circuitry at a switching speed. The device stress detector is configured to generate a device stress signal indicating an electrical characteristic at the switching element while the driver circuitry controls the switching element at a switching speed. The buffer circuitry is configured to generate, based on the device stress signal, an overstress signal indicating whether the electrical characteristic at the switching element satisfies a threshold value. The switching speed controller is configured to generate, based on the overstress signal, a switching speed signal indicating a change to the switching speed and output the switching speed signal to the driver circuitry. The driver circuitry is further configured to control, based on the switching speed signal, the switching element at a modified switching speed.

In some examples, the disclosure describes a method comprising generating a device stress signal indicating an electrical characteristic at a switching element of power converter circuitry while driver circuitry controls the switching element at a switching speed and generating, based on the device stress signal, an overstress signal indicating whether the electrical characteristic at the switching element satisfies a threshold value. The method further includes generating, based on the overstress signal, a switching speed signal indicating a change to the switching speed and outputting the switching speed signal to the driver circuitry, wherein the driver circuitry is configured to control, based on the switching speed signal, the switching element at a modified switching speed.

Details of these and other examples are set forth in the accompanying drawings and the description below. Other features, objects, and advantages will be apparent from the description and drawings, and from the claims.

### BRIEF DESCRIPTION OF DRAWINGS

FIG. 1 is a block diagram illustrating an example system for switching speed control, in accordance with one or more techniques of this disclosure.

FIG. 2 is a circuit diagram illustrating example power converter circuitry, in accordance with one or more techniques of this disclosure.

FIG. 3 is a circuit diagram illustrating an example circuit for switching speed control, in accordance with one or more techniques of this disclosure.

FIG. 4 is a conceptual diagram illustrating an example semiconductor circuit, in accordance with one or more techniques of this disclosure.

FIG. 5 is a flowchart illustrating an example process for switching speed control, in accordance with one or more techniques of the disclosure.

### DETAILED DESCRIPTION

Device stress signals, such as voltage spikes, may occur in power converter circuitry (e.g., an integrated DC/DC converter) due to, for example, printed circuit board (PCB) and package connections. For example, PCBs and package connections may include an inductance of a few nanohenries, which may vary depending on the PCB layout and/or package. These spikes can overstress the components during normal operation, posing a threat to the reliability of the power converter circuitry. The magnitude of spikes may be highly dependent on the PCB layout. Moreover, the overshoot value may be difficult to predict during an integrated circuit (IC) design phase, which may negatively impact the reliability of the power converter circuitry.

To address at least some of the foregoing, some systems may use one or more of an RC snubber circuit, higher voltage class switching elements, and/or gate resistors. RC snubber circuits may be costly, use a large amount of PCB area, reduce a conversion efficiency of the power converter circuitry, and/or be PCB layout dependent. The use of switches/MOSFETs with a higher voltage class (e.g., overengineering) may be silicon-area inefficient (in particular, if power converter circuitry is integrated), reduce a conversion efficiency, and can lead to voltage class violation based on a selected PCB layout. The use of gate resistors and/or weak drivers (e.g., low dU/dt) may reduce a conversion efficiency of the power converter circuitry, particularly in compact PCB layout designs.

Moreover, relying on one or more of an RC snubber circuit, higher voltage class switching elements, and/or gate resistors may not allow for a reliable way to assess whether or not a switching element (e.g., power transistors) on the die are overstressed or not. While technicians may probe an overshoot at the pin level and compare the measured value to the maximum pin ratings, the voltage at the pin level may not accurately represent device stress. For example, the on-chip overshoot may be higher than the overshoot measured at the pin-level, and special care must be taken in the choice and connection of the oscilloscope probes and oscilloscope settings to obtain meaningful measurement results. To summarize, there is a risk that some PCBs may lead to on-chip device overstress (e.g., transistor overstress), which may not be predicted or detected in a reliable manner.

In general, this disclosure is directed to techniques for adjusting a switching speed for controlling a switching element of power converter circuitry based on a device stress signal. For example, a circuit itself may generate a device stress signal indicating an electrical characteristic (e.g., a voltage or a current) at the switching element while controlling the switching element at a switching speed. In this example, the circuit may generate a switching speed signal indicating a change (e.g., increase or decrease) to the switching speed based on an overstress signal. In this way, the circuit may dynamically adjust the switching speed in order to maximize a conversion efficiency (e.g., maximize a switching speed) on operating condition(s) while helping to ensure that electrical characteristics are below thresholds (e.g., reducing or avoiding voltage/current overstress).

Taking as an example an asynchronous Buck converter, a two peak detector circuit can be used to measure both high side (HS) switch and free-wheeling diode (or LS switch) peak voltages during normal switching operation. Scaling down the measured peaks and comparing the scaled voltage to a reference, the circuit can determine whether either the HS switch or the free-wheeling diode are overstressed and/or have margin against respective maximum voltage usage. Based on this information, the circuit may adjust the HS switch turn-off and turn-on speed in order to help to maximize conversion efficiency on every operating condition while keeping under control components voltage overstress. In other words, the circuit (e.g., an IC) itself may measure the harmful overshoot and generates a baseband feedback signal. The circuit (or another circuit) may use this feedback signal to achieve optimum conversion efficiency (e.g., minimal power losses) while at the same time ensuring excellent reliability.

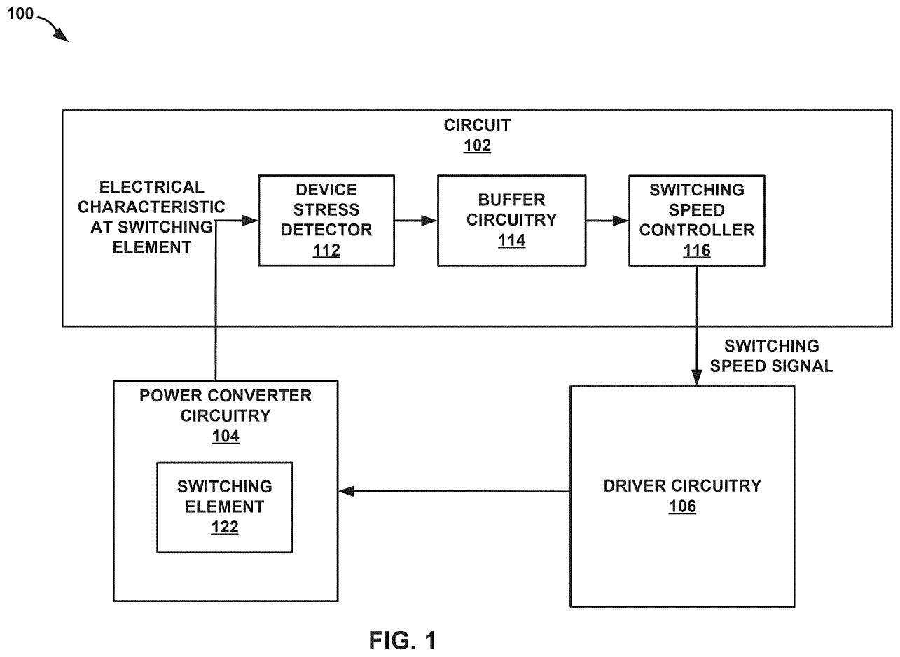

FIG. 1 is a block diagram illustrating an example system 100 for switching speed control, in accordance with one or more techniques of this disclosure. As illustrated in the example of FIG. 1, system 100 may include circuit 102, power converter circuitry 104, and driver circuitry 106. Circuit 102 includes device stress detector 112, buffer circuitry 114, and switching speed controller 116. Power converter circuitry 104 may include switching element 122.

Circuit 102 may be configured to control a switching speed of switching element 122. For example, circuit 102 may output a switching speed signal to driver circuitry 106, which may control, based on the switching speed signal, switching element 122. Circuit 102 may include one or more processors, such as one or more microprocessors, digital signal processors (DSPs), application specific integrated circuits (ASICs), field programmable gate arrays (FPGAs), or any other equivalent integrated or discrete logic circuitry, as well as any combinations of such components. The term “processor” or “processing circuitry” may generally refer to any of the foregoing logic circuitry, alone or in combination with other logic circuitry, or any other equivalent circuitry.

Power converter circuitry 104 may include DC/DC, AC/DC, DC/AC and/or AC/AC converters, inverters, flyback converters, switched-mode power supplies, switching current sources (LED drivers), or other types of circuitry configured to control power. In some examples, power converter circuitry 104 may include single-phase and/or multi-phase converters. Power converter circuitry 104 may include converters with monolithically integrated or external power transistors. In some examples, power converter circuitry 104 may include chiplet solutions, multi-die, and/or single-die packaging techniques. Examples of switching elements may include, but are not limited to, a silicon-controlled rectifier (SCR), a Field Effect Transistor (FET), and a bipolar junction transistor (BJT). Examples of FETs may include, but are not limited to, a junction field-effect transistor (JFET), a metal-oxide-semiconductor FET (MOSFET), a dual-gate MOSFET, an insulated-gate bipolar transistor (IGBT), any other type of FET, or any combination of the same. Examples of MOSFETS may include, but are not limited to, a depletion mode p-channel MOSFET (PMOS), an enhancement mode PMOS, depletion mode n-channel MOSFET (NMOS), an enhancement mode NMOS, a double-diffused MOSFET (DMOS), any other type of MOSFET, or any combination of the same. Examples of BJTs may include, but are not limited to, PNP, NPN, heterojunction, or any other type of BJT, or any combination of the same. It should be understood that switching elements may be high-side or low-side switching elements. Additionally, switching elements may be voltage-controlled and/or current-controlled. Examples of current-controlled switching elements may include, but are not limited to, gallium nitride (GaN) MOSFETs, BJTs, or other current-controlled elements.

In accordance with the techniques of the disclosure, device stress detector 112 may generate a device stress signal indicating an electrical characteristic at switching element 122 of power converter circuitry 104 while driver circuitry 106 controls switching element 122 at a switching speed. An electrical characteristic at switching element 122 may include, for example, a voltage or a current. Examples of an electrical characteristic that includes a voltage may include, for example, a differential voltage at terminals and/or pins and/or or a non-differential voltage. An example of a differential voltage may include, for example, a drain-to-gate voltage, a source-to-gate voltage, a source-to-drain voltage, an anode-cathode voltage or other differential voltage such as, for example, voltages associated with bipolar transistors, IGBTs, GaN, and/or other devices. Examples of an electrical characteristic that includes a current may include, for example, a measured current (e.g., using a current sensor IC and/or current sensor circuit). An electrical characteristic may be caused by switching element 122 and/or by other components of circuit 102 and/or outside of circuit 102. For example, an electrical characteristic may include a ground bounce, a ground oscillation, a power rail bounce, a power rail oscillation, or a differential transient between power and/or ground rails.

For example, device stress detector 112 may generate a device stress signal indicating a plurality of voltage values (e.g., drain-to-source voltages) or a peak voltage value (e.g. a peak drain-to-source voltage) at switching element 122. While this example refers to an electrical characteristic as a voltage, in other examples an electrical characteristic may refer to, for example, an electrical current.

Buffer circuitry 114 may be configured to generate, based on the device stress signal, an overstress signal indicating whether the electrical characteristic at switching element 122 satisfies a threshold value. For example, buffer circuit 114 may indicate whether the device stress level exceeds a reference signal. For instance, buffer circuitry 114 may include a comparator configured to compare the device stress signal to a reference signal and to output the overstress signal. In some examples, buffer circuit 114 may include an analog-to-digital converter (ADC) configured to generate a plurality of digital values based on the device stress signal and generate the overstress signal to indicate a representative digital value for the plurality of digital values. In some examples, buffer circuitry 114 may generate, based on the device stress signal, an error signal to cause circuit 102 to change to an error state (e.g., safe shutdown state) and/or to report the error to an external device.

Switching speed controller 116 may generate, based on the overstress signal, a switching speed signal indicating a change to the switching speed and output the switching speed signal to driver circuitry 106. For example, switching speed controller 116 may generate the switching speed signal to indicate increasing the switching speed in response to the overstress signal indicating that a peak voltage at the switching element is less than the threshold value. In this example, switching speed controller 116 may generate the switching speed signal to indicate decreasing the switching speed in response to the overstress signal indicating that the peak voltage at the switching element is greater than the threshold value. For example, the switching speed may indicate one or more of a rising slope value of a pulse modulated signal controlling switching element 122 or a falling slope value of the pulse modulated signal controlling switching element 122.

In some examples, switching speed controller 116 may generate the switching speed signal to indicate a difference in switching speed from an instant switching speed. For example, switching speed controller 116 may generate the switching speed signal to indicate whether to increase or decrease the switching speed. In particular, switching speed controller 116 may generate the switching speed signal to indicate only a ‘+1’ or a ‘−1’. In this example, driver circuitry 106 (or other circuitry) may determine the switching speed by incrementing the current speed by the indication of whether to increase or decrease the switching speed.

In some examples, switching speed controller 116 may itself determine a modified switching speed based on the switching speed and the determination of whether to increase or decrease the switching speed and generate the switching speed signal to indicate the modified switching speed. For example, switching speed controller 116 may include a data register configured to store at least first data and second data. In this example, switching speed controller 116 may generate the switching speed signal to indicate the first data (e.g., a first switching speed) in response to the overstress signal indicating that the electrical characteristic at switching element 122 satisfies the threshold value and to indicate the second data (e.g., a second switching speed) in response to the overstress signal indicating that the electrical characteristic at switching element 122 does not satisfy the threshold value. Switching speed controller 116 may modify the switching speed signal in discrete steps or continuously. Switching speed controller 116 may form an analog regulation loop that drives the switching speed signal based on the overstress signal and/or stress signal.

Driver circuitry 106 may be configured to control, based on the switching speed signal, switching element 122 at a modified switching speed. The switching speed may include one or more of a rising slope value of a pulse modulated signal controlling switching element 122 or a falling slope value of the pulse modulated signal controlling switching element 122. For example, driver circuitry 106 may control the switching element 122 at the modified switching speed by modifying a control node current or a control node voltage applied to switching element 122. For instance, driver circuitry 106 may control switching element 122 at the modified switching speed by modifying a gate current (e.g., a slope value or rise time) applied to switching element 122. Driver circuitry 106 may increase the gate current (e.g., a slope value of the gate current) applied to switching element 122 to increase the switching speed and may decrease the gate current applied to switching element 122 to decrease the switching speed.

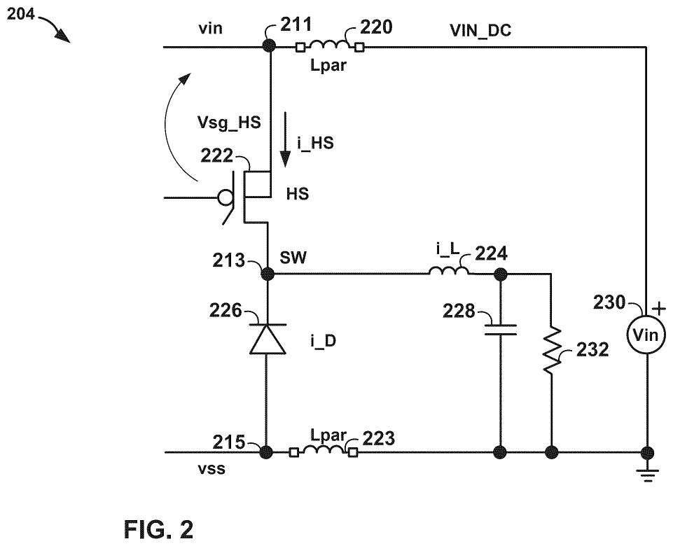

FIG. 2 is a circuit diagram illustrating example power converter circuitry 204, in accordance with one or more techniques of this disclosure. FIG. 2 is discussed with FIG. 1 for example purposes only.

In the example of FIG. 2, power converter circuitry 204 comprises a Buck converter including a p-type HS switch 222 and a free-wheeling diode 226. In this example, HS switch driver speed (both turn-on and turn-off) affects the voltage overstress of either HS switch and free-wheeling diode (or LS switch). As shown, DC/DC connections to ground and input voltage are non-ideal, and the non-ideality is represented as parasitic inductance 220, 223 (Lpar). Power converter circuitry 204 further includes inductance 224, capacitance 228, resistance 232, and a supply 230.

Parasitic inductance 220, 223 may be responsible for the voltage spikes during normal switching activity. For example, the faster HS switch 222 is turned on, the faster a high side current “i_HS” rises. Similarly, the faster HS switch 222 is turned off, the faster the high side current “i_HS” decreases. When HS switch 222 is turned on, the positive derivative of the high side current “i_HS” makes node 211 “vin” drop with respect to the voltage “VIN_DC” output by supply 230. The voltage drop at node 211 can be calculated as Lpar*d(i_HS)/dt, where Lpar is the inductance of parasitic inductance 220 and i_HS is the high side current at HS switch 222. In this example, when the high side current reaches the value to make switch (SW) node 213 rise, the energy stored in parasitic inductance 220, 223 starts resonating with capacitance at node 211, making node 211 oscillate around DC value VIN_DC. The overshoot from the oscillation is directly proportional to the voltage drop at node 211 and is therefore directly proportional to the parasitic inductance from parasitic inductance 220, 223 Lpar and d(i_HS)/dt, which is all proportional to the HS driver turn-on speed.

Moreover, a peak reverse voltage may occur because free-wheeling diode 226 is connected between SW node 213 and vss node 215, and because SW node 213 is shorted to vin through HS switch 222. The peak reverse voltage of the free-wheeling diode 226 is higher than the DC input voltage of supply 230. This voltage spike can affect diode reliability of free-wheeling diode 226 and/or reliability of a low-side MOSFET connected between SW node 213 and vss node 215. In some examples, free-wheeling diode 226 may be the body diode of a N-type MOSFET.

When HS switch 222 is turned off, the negative derivative of the high side current “i_HS” makes node 211 “vin” to rise with respect to the voltage “VIN_DC” output by supply 230. The voltage spike when HS switch 222 is turned off can be calculated as before as Lpar*d(i_HS)/dt. The faster the HS driver speed in the turn-off phase the higher the voltage spike. Moreover, a peak drain-source voltage at HS switch 222 may occur because HS switch 222 is connected between node 211 and SW node 213, and because SW node 213 drops to a reference voltage “vss.” The peak drain-source voltage at HS switch 222 is higher than the DC input voltage “VIN_DC” of supply 230. This peak drain-source voltage can affect a reliability of HS switch 222 (e.g., the gate-drain or the drain-source voltage of HS switch 222 can exceed the safe operating area if the inductance Lpar is sufficiently high).

Based on the foregoing, both voltage overshoot of HS switch 222 and free-wheeling diode 226 (or LS switch) may increase with increasing parasitic inductance from parasitic inductance 220, 223, and that free-wheeling diode 226 (or LS switch) peak voltage depends on turn-on speed of HS switch 222, while HS switch peak voltage depends on turn-off speed of HS switch 222 itself.

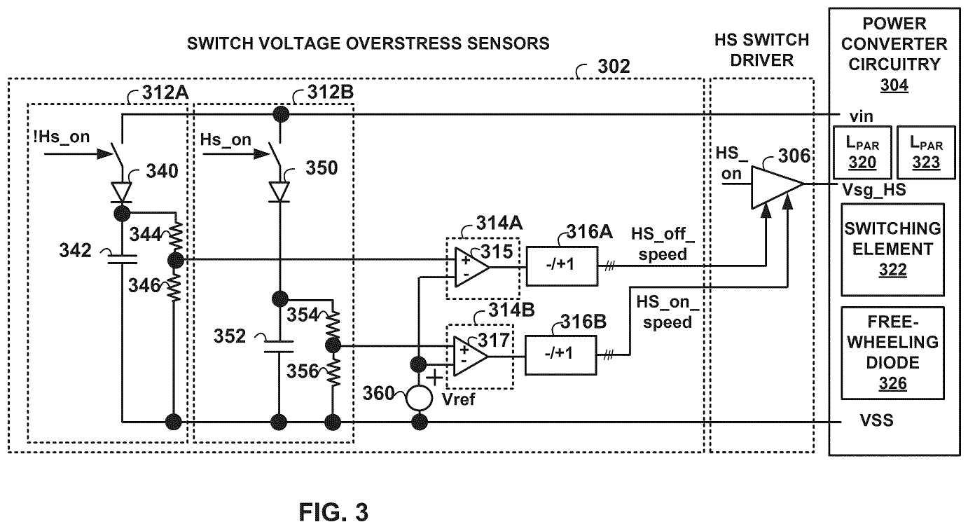

FIG. 3 is a circuit diagram illustrating an example circuit 302 for switching speed control, in accordance with one or more techniques of this disclosure. FIG. 3 is discussed with FIG. 1-2 for example purposes only. Circuit 302 includes device stress detectors 312A, 312B, buffer circuitry 314A, 314B, and switching speed controllers 316A, 316B. Power converter circuitry 304 may include switching element 322, free-wheeling diode 326, and parasitic inductance 320, 323. In some examples, power converter circuitry 304 may be consistent with power converter circuitry 204 of FIG. 2.

Circuit 302 may be configured to monitor device stress. For example, circuit 302 may monitor a voltage overstress of both free-wheeling diode 326 (or LS switch) and HS switch 322, and adjusting a HS driver speed to reduce the voltage overstress to desirable values among all possible operative conditions of power converter circuitry 204. In the example of FIG. 3, device stress detectors 312A, 312B monitor device stress. While this example is directed to a voltage-detection circuit, techniques described herein may include any stress-detection circuit resulting in an analog/digital baseband signal that is a monotonic function of, for example, the drain-gate and/or drain-source and/or anode-cathode stress voltage.

In the example of FIG. 3, stress detector 312B includes diode 350, capacitor 352, and a resistor divider formed by resistors 354, 356. Stress detector 312A may be activated by the negated version of a high side switching signal “hs_on signal”, represented as “!hs_on.” As stress detector 312A is active during HS off phase, stress detector 312A monitors a voltage overstress at HS switch 222. Stress detector 312A includes diode 340, capacitor 342, and a resistor divider formed by resistors 344, 346. In this example, stress detector 312B is active during HS on phase and monitors voltage overstress at free-wheeling diode 326 (or LS switch).

The voltage divider circuitry (e.g., a voltage divider) formed by resistors 344, 346 is configured to scale down a sensed voltage stored by capacitor 342 (e.g., an analog baseband signal). For example, capacitor 342 may be configured to store a voltage at switching element 322 while switching element 322 is controlled at a switching speed. In this example, the voltage divider circuitry is configured to generate the device stress signal from the voltage stored at capacitor 342. While the voltage divider circuitry of stress detector 312A includes a voltage divider (e.g., a resistor divider), in some examples, voltage divider circuitry may include, for example, one or more of a voltage divider, a capacitor divider, or a voltage buffer. In this example, stress detector 312A generates the device stress signal indicating the sensed voltage at HS switch 322. In this example, comparator 315 compares the scaled down sensed voltage to a fixed voltage reference Vref. That is, buffer circuitry 314A generates, based on the device stress signal, an overstress signal indicating whether the sensed voltage at HS switch 322 satisfies a threshold value (i.e., the fixed voltage reference 360 “Vref”). Similarly, the resistor divider formed by resistors 354, 356 scales down a sensed voltage stored by capacitor 352 (e.g., analog baseband signal). That is, device stress detector 312B may generate a device stress signal indicating the sensed voltage at free-wheeling diode 326 (or LS switch). In this example, comparator 317 compares the scaled down sensed voltage to a fixed voltage reference Vref. That is, buffer circuitry 314B generates, based on the device stress signal, an overstress signal indicating whether the sensed voltage at free-wheeling diode 326 (or LS switch) satisfies a threshold value (i.e., the fixed voltage reference 360 “Vref”). In this way, buffer circuitry 314A, 314B may determine, using the resistor dividers and voltage reference 360, whether device stresses are within allowed limits or not (e.g., whether the safe operating area of any device is violated).

For example, buffer circuitry 314B may detect that the device stress signal (e.g., the scaled sensed voltage “peak_sense_on_phase”) is less than the threshold value (e.g., the fixed voltage reference 360 “Vref”). In response to detecting that the device stress signal is less than the threshold value, buffer circuitry 314B may generate an overstress signal indicating ‘0’. In contrast, buffer circuitry 314B may generate an overstress signal indicating ‘1’ in response to detecting that the device stress signal is greater than the threshold value.

In accordance with the techniques of the disclosure, switching speed controllers 316A, 316B may control the switching speed based on the overstress signal. For example, switching speed controller 316 may generate a digital signal (or analog) indicating a change (e.g., ‘0’ to slow down or ‘1’ to speed up or a complete value for a modified switching speed) to the switching speed based on the overstress signal. For instance, an output of comparator 317 may be fed to switching speed controller 316B, which may dynamically increase or decrease by one least significant bit (LSB) the turn-on speed of HS driver 322 (e.g., a digital register) in each clock-cycle. That is, switching speed controller 316B may output a change to increase by one LSB the turn-on speed of HS driver 322 in each clock-cycle. Increasing the turn-on speed of HS switch 322 can increase the voltage overshoot seen by free-wheeling diode 226 (or LS switch). Switching speed controller 316B may continue increasing the switching speed until the device stress signal (e.g., the scaled sensed voltage “peak_sense_on_phase”) is less than the threshold value (e.g., the fixed voltage reference 360 “Vref”). When this happens, buffer circuitry 314B, or more particularly comparator 317, may generate an overstress signal indicating ‘1’. In response to the overstress signal indicating ‘1’, switching speed controller 316B may output a change to decrease by one LSB the turn-on speed of HS driver 322. Switching speed controller 316 may modify the switching speed signal in discrete steps or continuously. Switching speed controller 316 may form an analog regulation loop that drives the switching speed signal based on the overstress signal and/or stress signal.

In this way, switching speed controller 316B may represent a digital regulation loop, where the turn-on speed is regulated such that the device stress is at its optimal target value (e.g., digitally one LSB below a speed where the overstress signal indicates ‘1’). In this example, in steady state conditions this process will be iterated, and turn-on speed of the HS driver 306 can oscillate by +/−1 LSB around the optimal value. Similarly, device stress detector 312A, buffer circuitry 314A, and switching speed controller 316 may represent a digital regulation loop, where the turn-off speed is regulated such that the device stress is at its optimal target value. While this example uses a single comparator to detect whether an electrical characteristic satisfies a threshold value, in other examples, may use multiple comparators to detect whether an electrical characteristic satisfies a threshold value and/or may use an ADC converter to detect whether an electrical characteristic satisfies a threshold value.

Referring to parasitic inductance 320, 323 (Lpar), switching speed controllers 316A, 316B may automatically adjust, for a particular value of the parasitic inductance, the turn-on and/or turn-off speed in order to oscillate around and/or approach the optimal value. For example, with a constant switching speed, a difference in a voltage overshoot between the parasitic inductance with values of a 1 nH, 2 nH, and 3 nH may be almost 30%. In this example, for the parasitic inductance of 1 nH, the high side switching speed can be turned-on to a relatively fast speed while ensuring device stresses are within allowed limits. In contrast, for the parasitic inductance of 2 nH, the high side switching speed can be turned-on to a relatively moderate speed and, for the parasitic inductance of 3 nH, the high side switching speed can be turned-on to a relatively slow speed to ensure device stresses are within allowed limits. In order to help to achieve a desirable switching speed, switching speed controllers 316A, 316B may keep the electrical characteristic close to a threshold. For example, switching speed controllers 316A, 316B may keep a peak voltage close to a voltage reference. When switching speed controllers 316A, 316B control the switching speed to the optimal level, a difference in a peak voltage at free-wheeling diode 326 between the parasitic inductance with values of 1 nH, 2 nH, and 3 nH may be reduced to less than 6%.

Moreover, in response to changes of operating conditions (e.g. a supply voltage “VIN_DC” is changed and/or a load current is changed, circuit 302 may automatically adjust the turn-on and/or turn-off speed in order to again oscillate around and/or approach the optimal value. In this way, switching speed controllers 316A, 316B may control devices reliability, as well help to maximize power converter circuitry efficiency among all possible operating conditions.

For example, if static input voltage decrease, DC/DC components are less overstressed. In this example, switching speed controllers 316A, 316B may increase the HS driver speed to account for the additional tolerance for voltage spikes while maintaining devices reliability. For example, when the supply voltage “VIN_DC” output by supply 230 of FIG. 2 decreases, the source-to-drain peak voltage at HS switch 222 (“SW-vss”) may initially decrease. However, switching speed controllers 316A, 316B may react by increasing the HS driver turn-on speed (e.g., a high side current rise time of 800 A/μs) to maintain a peak voltage of a SW-vss constant.

When the input voltage is higher, however, the high side current “i_HS” may raise slower (e.g., a high side current rise time of 750 A/μs) due to the lower speed of HS driver 306, which may result in a voltage overshoot of 1 V with respect to the supply voltage “VIN_DC.” When the input voltage is lower, switching speed controller 316A may increase the HS driver turn-on speed, leading to a higher high-side current “i_HS” rise time, which may result in 1.3 V overshoot with respect to the supply voltage “VIN_DC.” Similarly, switching speed controller 316B may regulate the switching speed to keep a peak voltage at free-wheeling diode 326 (or a LS switch) almost constant. In this way, switching speed controllers 316A, 316B may regulate the switching speed to achieve a better conversion efficiency for power converter circuitry 304 compared to systems using a fixed HS driver speed) due to a selection of an optimized switching speed, which is able to reduce switching losses while keeping under control voltage overstress of components of the power converter circuitry.

In some examples, circuit 302 may output the sensed stress signal at an IC pin and/or into an ADC converter. In this example, the ADC or the pin could be shared among multiple functions. For example, an analog multiplexer could be used switch the voltage outputted through a multi-functional pin from different sources, where one source is the sensed stress signal. If an A/D converter is used, the generated digital signal can be further processed inside the IC or it could also be read by another IC via a digital interface, e.g., a serial peripheral interface (SPI).

Techniques described herein for controlling switching speed may include one or more of the following dimensions.

A first dimension (1) includes the time at which the feedback/stress signal is read. In a first aspect of the first dimension (1A), the feedback/stress signal is dynamically exploited while the system is running, e.g., a regulation loop is formed. In a second aspect of the first dimension (1B), the feedback/stress signal is only read during power-up. In a third aspect of the first dimension (1C), the feedback/stress signal is only read after or during production or re-calibration of a system. In a fourth aspect of the first dimension (1D), the feedback/stress signal is only read during characterization or qualification of a system.

A second dimension includes an analog or a digital signal. In a first aspect of the second dimension (2A), the feedback/stress signal is processed in an analog manner only. In a second aspect of the second dimension (2B), one or multiple comparators read the initial analog feedback/stress signal and result in multiple digital signals. In a third aspect of the second dimension (2C), an ADC reads the initial analog feedback/stress signal and results in a binary or otherwise encoded number.

A third dimension includes how the feedback/stress signal is processed to result in a tuning or optimization of the gate driver speed. In a first aspect of the third dimension (3A), the feedback/stress signal is fully processed on the same die where the power transistors reside. In a second aspect of the third dimension (3B), the feedback/stress signal is processed on a separate die in the same or a separate IC-package and/or PCB. In a third aspect of the third dimension (3C), the feedback/stress signal is processed on a computer, oscilloscope or other separate test-instrument and, e.g., is displayed to a human operator, who then decides about the optimal gate driver speed.

To illustrate the three dimensions, consider, for instance, the combination (1D)+(2A)+(3C). In this example, the output of the analog peak-detectors (e.g., peak_sense_on_phase) may be fed into an analog multiplexer and then into an analog voltage follower. The analog voltage follower may drive a multi-functional pin of the IC. When the PCB-design is qualified, the IC is in a special test-mode, in which the analog multiplexer forwards the feedback/stress signal to the multi-functional pin. Subsequently, an oscilloscope or multimeter may be connected to a multi-functional pin via a specific test-point. By sending SPI-commands to the IC, the HS switch driver speed can be tuned based on the effect on the feedback/stress signal.

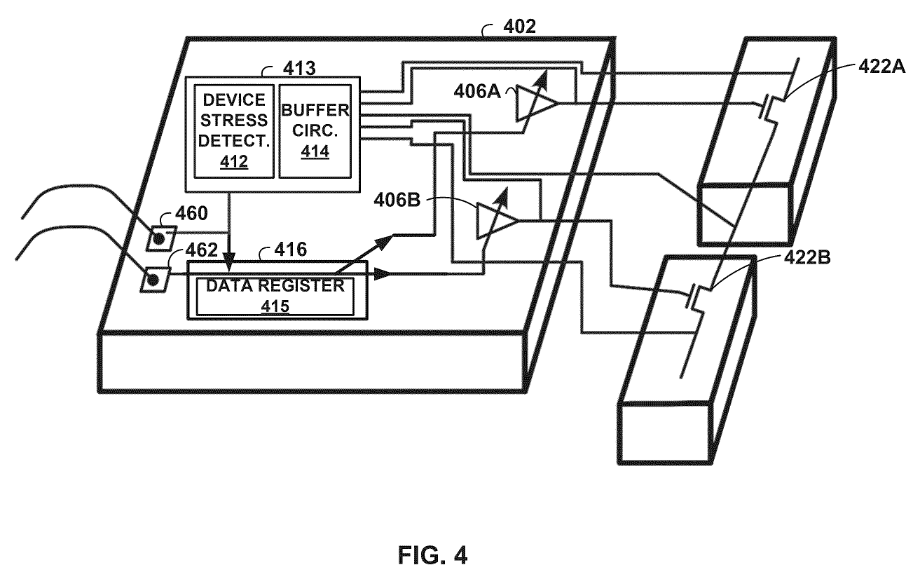

FIG. 4 is a conceptual diagram illustrating an example semiconductor circuit 402, in accordance with one or more techniques of this disclosure. FIG. 4 is discussed with FIG. 1-3 for example purposes only. Semiconductor circuit 402 includes adjustable speed driver circuitry 406A, 406B, safe operating area (SOA) supervisor 413, switching elements 422A, 422B, switching speed controller 416, device stress signal pin 460, and control pin 462. SOA supervisor 413 may include device stress detector 412 and buffer circuitry 414. Semiconductor circuit 402 may represent, for example, a printed circuit board, an integrated circuit package, or a die.

Adjustable speed driver circuitry 406A may represent, for example, an adjustable driver and control circuit configured to control switching element 422A. For example, driver circuitry 406A may acts on a power transistor to control an electrical current (e.g., dI/dt) change at switching element 422A. Adjustable speed driver circuitry 406A may include, for example, a DC/DC gate drivers, fully integrated). Similarly, adjustable speed driver circuitry 406B may represent, for example, an adjustable driver and control circuit configured to control switching element 422B. For example, adjustable speed driver circuitry 406B may act on a power transistor to control an electrical current (e.g., dI/dt) change at switching element 422B.

Switching elements 422A, 422B may represent, for example, power transistors under “supervision.” While the example of FIG. 4 includes switching elements, other examples may include one switching element or more than two switching elements. For example, a semiconductor circuit may include ‘N’ number of switching elements, where N is greater than 2, for a power converter with more than one switching element (e.g., a half-bridge power converter).

SOA supervisor 413 may “sense” whether a SOA of supervised devices is violated. For example, SOA supervisor 412 may perform the functions of device stress detector 112 and/or buffer circuitry 114 of FIG. 1. For instance, SOA supervisor 412 may represent a peak-detector for a voltage drain-to-source “V(Drain, Source).” As shown in FIG. 4., SOA supervisor 413 may be connected to switching elements 422A, 422B via an arbitrary number of sense wires of semiconductor circuit 402.

In the example of FIG. 4, semiconductor circuit 402 includes device stress signal pin 460, which may be configured to allow for the device stress signal and/or the overstress signal to be output from semiconductor circuit 402. For example, SOA supervisor 413 may generate a plurality of digital values based on the device stress signal. In this example, SOA supervisor 413 may generate the overstress signal to indicate a representative digital value (e.g., a peak voltage) for the plurality of digital values. In some examples, SOA supervisor 413 may generate the overstress signal to indicate a respective digital value for each sample (e.g., each sampled voltage) of the device stress signal.

Stress signal pin 460 may be a multi-functional pin configured to output and/or receive another signal. In some examples, however, stress signal pin 460 may be omitted. Similarly, semiconductor circuit 402 includes control pin 462, which is configured to receive an input signal for an adjustable gate driver/control circuit provided from outside (e.g., an extra pin or SPI, etc.).

As shown in FIG. 4, device stress detector 412, adjustable speed driver circuitry 406A, 406B, and switching speed controller 416 may be formed on a single semiconductor circuit (i.e., semiconductor circuit 402). In the example of FIG. 4, switching elements 422A, 422B are formed on different semiconductor circuits. However, in some examples, switching elements 422A, 422B may be formed on the single semiconductor circuit (i.e., semiconductor circuit 402. Moreover, in some examples, switching speed controller 416 may be formed on a different semiconductor circuit (e.g., a second semiconductor circuit) than semiconductor circuit 402.

In some examples, switching speed controller 416 may optionally include a data register 415 configured to store at least first data and second data. In this example, switching speed controller 416 may generate the switching speed signal to indicate the first data (e.g., a first switching speed) in response to the overstress signal indicating that the electrical characteristic at switching element 122 satisfies the threshold value and to indicate the second data (e.g., a second switching speed) in response to the overstress signal indicating that the electrical characteristic at switching element 122 does not satisfy the threshold value. For instance, the first data may indicate to increase the switching speed (e.g., by one LSB or ‘N’ number of LSBs) and the second data may indicate to decrease the switching speed (e.g., by one LSB or ‘M’ number of LSBs).

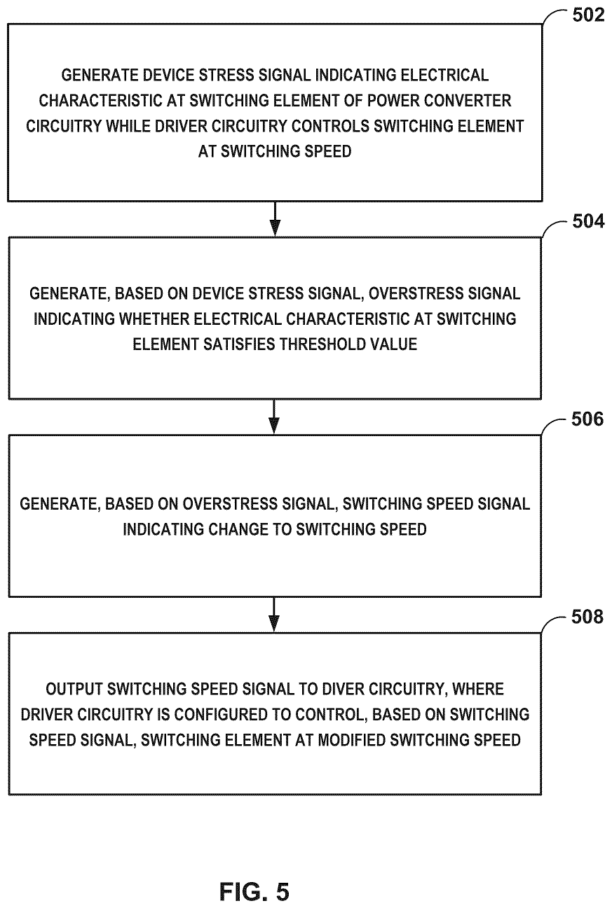

FIG. 5 is a flowchart illustrating an example process for switching speed control, in accordance with one or more techniques of the disclosure. FIG. 5 is discussed with FIG. 1-4 for example purposes only and the process of FIG. 5 could be performed by other circuits or devices.

Device stress detector 112 may generate a device stress signal indicating an electrical characteristic at switching element 122 of power converter circuitry 104 while driver circuitry 106 controls switching element 122 at a switching speed (502). For example, device stress detector 112 may include a capacitor configured to store a voltage at the switching element while the switching element is controlled at the switching speed. In some examples, device stress detector 112 may include voltage divider circuitry configured to generate the device stress signal from the voltage stored at the capacitor. The voltage divider circuitry may include one or more of a voltage divider, a capacitor divider, or a voltage buffer. The electrical characteristic at switching element 122 may include, for example, a voltage or a current.

Buffer circuitry 114 may generate, based on the device stress signal, an overstress signal indicating whether the electrical characteristic at switching element 122 satisfies a threshold value (504). For example, buffer circuitry 114 may include a comparator configured to compare the device stress signal to a reference signal and to output the overstress signal based on the comparison. In some examples, buffer circuitry 114 may include an ADC configured to generate a plurality of digital values based on the device stress signal and generate the overstress signal to indicate a representative digital value for the plurality of digital values.

Switching speed controller 116 may generate, based on the overstress signal, a switching speed signal indicating a change to the switching speed (506). For example, switching speed controller 116 may generate the switching speed signal to indicate increasing the switching speed in response to the overstress signal indicating that a peak voltage at the switching element is less than the threshold value. In this example, switching speed controller 116 may generate the switching speed signal to indicate decreasing the switching speed in response to the overstress signal indicating that the peak voltage at the switching element is greater than the threshold value. The switching speed may include one or more of a rising slope value of a pulse modulated signal controlling switching element 122 or a falling slope value of the pulse modulated signal controlling switching element 122. Switching speed controller 116 may generate the switching speed signal to indicate whether to increase or decrease the switching speed. For instance, switching speed controller 116 may generate the switching speed signal to indicate to increase the switching speed by one LSB. In some examples, however, switching speed controller 116 may generate the switching speed signal to determine the modified switching speed based on the switching speed and a determination of whether to increase or decrease the switching speed. In this example, switching speed controller 116 may generate the switching speed signal to indicate the modified switching speed (e.g., digital speed setting value 22).

Switching speed controller 116 may include an analog components and/or digital components. For example, switching speed controller 116 may include a data register configured to store at least first data and second data. In this example, switching speed controller 116 may generate the switching speed signal to indicate the first data in response to the overstress signal indicating that the electrical characteristic at switching element 122 satisfies the threshold value. In this example, switching speed controller 116 may generate the switching speed signal to indicate the second data in response to the overstress signal indicating that the electrical characteristic at switching element 122 does not satisfy the threshold value.

Switching speed controller 116 may output the switching speed signal to driver circuitry 106, where driver circuitry 106 is configured to control, based on the switching speed signal, switching element 122 at a modified switching speed. For example, driver circuitry 106 may modify a control node current or a control node voltage (e.g., a rise time) applied to switching element 122.

In some examples, device stress detector 112, driver circuitry 106, and switching speed controller 116 are formed on a single semiconductor circuit. The single semiconductor circuit may include a printed circuit board, an integrated circuit package, or a semiconductor die. In some examples, switching element 122 is formed on the single semiconductor circuit. However, in other examples, switching element 122 is formed on a second semiconductor circuit different from the single semiconductor circuit.

In some examples, wherein device stress detector 112 and driver circuitry 106 are formed on a first semiconductor circuit. The first semiconductor circuit may include a printed circuit board, an integrated circuit package, or a die. In this example, switching speed controller 116 may be formed on a second semiconductor circuit.

The techniques described in this disclosure may be implemented in circuitry. In various examples, the techniques may be implemented, at least in part, in circuitry, hardware, software, firmware or any combination thereof. For example, various aspects of the described techniques may be implemented within one or more logical elements, processors, including one or more microcontrollers, microprocessors, digital signal processors (DSPs), application specific integrated circuits (ASICs), field programmable gate arrays (FPGAs), or any other equivalent integrated or discrete logic circuitry, as well as any combinations of such components. The term “processor” or “processing circuitry” may generally refer to any of the foregoing logic circuitry, alone or in combination with other logic circuitry, or any other equivalent circuitry. A control unit comprising hardware may also perform one or more of the techniques of this disclosure.

Such circuitry, hardware, software, and firmware may be implemented within the same device or integrated circuit or within separate devices to support the various operations and functions described in this disclosure. In addition, any of the described units, modules or components may be implemented together or separately as discrete but interoperable logic devices. Depiction of different features as modules or units is intended to highlight different functional aspects and does not necessarily imply that such modules or units must be realized by separate hardware or software components. Rather, functionality associated with one or more modules or units may be performed by separate hardware or software components or integrated within common or separate hardware or software components.

It may also be possible for one or more aspects of this disclosure to be performed in software, e.g., especially for logic or decisions that are preformed based on circuit output, in which case those aspects of the techniques described in this disclosure may also be embodied or encoded in a computer-readable medium, such as a computer-readable storage medium, containing instructions. Instructions embedded or encoded in a computer-readable storage medium may cause a processor, to perform the method, e.g., when the instructions are executed. The instructions, in this example, may be stored in a memory, which may comprise random access memory (RAM), read only memory (ROM), programmable read only memory (PROM), erasable programmable read only memory (EPROM), electronically erasable programmable read only memory (EEPROM), flash memory, or other computer readable media.

The following clauses may illustrate one or more aspects of the disclosure.

Clause 1: A circuit comprising: a device stress detector configured to generate a device stress signal indicating an electrical characteristic at a switching element of power converter circuitry while driver circuitry controls the switching element at a switching speed; buffer circuitry configured to generate, based on the device stress signal, an overstress signal indicating whether the electrical characteristic at the switching element satisfies a threshold value; and a switching speed controller configured to generate, based on the overstress signal, a switching speed signal indicating a change to the switching speed and output the switching speed signal to the driver circuitry, wherein the driver circuitry is configured to control, based on the switching speed signal, the switching element at a modified switching speed.

Clause 2: The circuit of clause 1, wherein the electrical characteristic comprises a voltage at the switching element and wherein, to generate the switching speed signal, the switching speed controller is configured to: generate the switching speed signal to indicate increasing the switching speed in response to the overstress signal indicating that a peak voltage at the switching element is less than the threshold value; and generate the switching speed signal to indicate decreasing the switching speed in response to the overstress signal indicating that the peak voltage at the switching element is greater than the threshold value.

Clause 3: The circuit of clause 2, wherein the switching speed comprises one or more of a rising slope value of a pulse modulated signal controlling the switching element or a falling slope value of the pulse modulated signal controlling the switching element, and wherein to control the switching element at the modified switching speed the driver circuit is configured to modify a control node current or a control node voltage applied to the switching element.

Clause 4: The circuit of any of clauses 1-3, wherein, to generate the switching speed signal, the switching speed controller is further configured to generate the switching speed signal to indicate whether to increase or decrease the switching speed.

Clause 5: The circuit of any of clauses 1-3, wherein, to generate the switching speed signal, the switching speed controller is configured to: determine, based on the overstress signal, whether to increase or decrease the switching speed; determine the modified switching speed based on the switching speed and the determination of whether to increase or decrease the switching speed; and generate the switching speed signal to indicate the modified switching speed.

Clause 6: The circuit of any of clauses 1-5, wherein the switching speed controller comprises a data register configured to store at least first data and second data; and wherein, to generate the switching speed signal, the switching speed controller is configured to generate the switching speed signal to indicate the first data in response to the overstress signal indicating that the electrical characteristic at the switching element satisfies the threshold value and to indicate the second data in response to the overstress signal indicating that the electrical characteristic at the switching element does not satisfy the threshold value.

Clause 7: The circuit of any of clauses 1-6, wherein the buffer circuitry comprises a comparator configured to compare the device stress signal to a reference signal and to output the overstress signal.

Clause 8: The circuit of any of clauses 1-6, wherein the buffer circuitry comprises an analog-to-digital converter configured to: generate a plurality of digital values based on the device stress signal; and generate the overstress signal to indicate a representative digital value for the plurality of digital values.

Clause 9: The circuit of any of clauses 1-8, wherein the device stress detector comprises: a capacitor configured to store a voltage at the switching element while the switching element is controlled at the switching speed; and voltage divider circuitry configured to generate the device stress signal from the voltage stored at the capacitor.

Clause 10: The circuit of clause 9, wherein the voltage divider circuitry comprises one or more of a voltage divider, a capacitor divider, or a voltage buffer.

Clause 11: The circuit of any of clauses 1-10, wherein the device stress detector, the driver circuitry, and the switching speed controller are formed on a single semiconductor circuit, the single semiconductor circuit comprising a printed circuit board, an integrated circuit package, or a semiconductor die.

Clause 12: The circuit of clause 11, wherein the switching element is formed on the single semiconductor circuit.

Clause 13: The circuit of any of clauses 1-10, wherein the device stress detector and driver circuitry are formed on a first semiconductor circuit, the first semiconductor circuit comprising a printed circuit board, an integrated circuit package, or a die; and wherein the switching speed controller is formed on a second semiconductor circuit.

Clause 14: The circuit of any of clauses 1-13, wherein the power converter circuitry comprises one or more of an DC/DC converter, an AC/DC converter, an DC/AC converter, an AC/AC converter, an inverter, a multi-phase inverter, a flyback converter, a switched-mode power supply, a switching current source, a class-D amplifier, a motor driver, a half-bridge, a full bridge, or a light emitting diode driver.

Clause 15: The circuit of any of clauses 1-14, wherein the electrical characteristic at the switching element comprises a voltage or a current

Clause 14: The system of clause 13, wherein to generate the output switching signal the comparison circuitry is configured to: generate the output switching signal to indicate a first phase when the voltage at the second capacitive element is greater than the voltage at the fourth capacitive element; and generate the output switching signal to indicate a second phase when the voltage at the second capacitive element is not greater than the voltage at the fourth capacitive element.

Clause 15: The system of any of clauses 12-14, wherein the second capacitive element comprises a first node and a second node; and wherein to discharge the second capacitive element the switching circuitry is configured to connect both the first node of the first capacitive element and the second node of the first capacitive element to a supply node.

Clause 16: A system comprising: driver circuitry configured to control a switching element of power converter circuitry at a switching speed; a device stress detector configured to generate a device stress signal indicating an electrical characteristic at the switching element while the driver circuitry controls the switching element at the switching speed; buffer circuitry configured to generate, based on the device stress signal, an overstress signal indicating whether the electrical characteristic at the switching element satisfies a threshold value; and a switching speed controller configured to generate, based on the overstress signal, a switching speed signal indicating a change to the switching speed and output the switching speed signal to driver circuitry, wherein the driver circuitry is further configured to control, based on the switching speed signal, the switching element at a modified switching speed.

Clause 17: The system of clause 16, wherein the electrical characteristic comprises a voltage at the switching element and wherein, to generate the switching speed signal, the switching speed controller is configured to: generate the switching speed signal to indicate increasing the switching speed in response to the overstress signal indicating that a peak voltage at the switching element is less than the threshold value; and generate the switching speed signal to indicate decreasing the switching speed in response to the overstress signal indicating that the peak voltage at the switching element is greater than the threshold value.

Clause 18: The system of clause 17, wherein the switching speed comprises one or more of a rising slope value of a pulse modulated signal controlling the switching element or a falling slope value of the pulse modulated signal controlling the switching element, and wherein to control the switching element at the modified switching speed the driver circuit is configured to modify a control node current or a control node voltage applied to the switching element.

Clause 19: The system of any of clauses 16-18, wherein, to generate the switching speed signal, the switching speed controller is further configured to generate the switching speed signal to indicate whether to increase or decrease the switching speed.

Clause 20: A method comprising: generating a device stress signal indicating an electrical characteristic at a switching element of power converter circuitry while driver circuitry controls the switching element at a switching speed; generating, based on the device stress signal, an overstress signal indicating whether the electrical characteristic at the switching element satisfies a threshold value; generating, based on the overstress signal, a switching speed signal indicating a change to the switching speed; and outputting the switching speed signal to the driver circuitry, wherein the driver circuitry is configured to control, based on the switching speed signal, the switching element at a modified switching speed.

Various aspects have been described in the disclosure. These and other aspects are within the scope of the following claims.

What is claimed is:

1. A circuit comprising:
a device stress detector configured to generate a device stress signal indicating an electrical characteristic at a switching element of power converter circuitry while driver circuitry controls the switching element at a switching speed;
buffer circuitry configured to generate, based on the device stress signal, an overstress signal indicating whether the electrical characteristic at the switching element satisfies a threshold value; and
a switching speed controller configured to generate, based on the overstress signal, a switching speed signal indicating a change to the switching speed and output the switching speed signal to the driver circuitry,
wherein the driver circuitry is configured to control, based on the switching speed signal, the switching element at a modified switching speed.

2. The circuit of claim 1, wherein the electrical characteristic comprises a voltage at the switching element and wherein, to generate the switching speed signal, the switching speed controller is configured to:
generate the switching speed signal to indicate increasing the switching speed in response to the overstress signal indicating that a peak voltage at the switching element is less than the threshold value; and
generate the switching speed signal to indicate decreasing the switching speed in response to the overstress signal indicating that the peak voltage at the switching element is greater than the threshold value.

3. The circuit of claim 2,
wherein the switching speed comprises one or more of a rising slope value of a pulse modulated signal controlling the switching element or a falling slope value of the pulse modulated signal controlling the switching element, and
wherein to control the switching element at the modified switching speed the driver circuit is configured to modify a control node current or a control node voltage applied to the switching element.

4. The circuit of claim 1, wherein, to generate the switching speed signal, the switching speed controller is further configured to generate the switching speed signal to indicate whether to increase or decrease the switching speed.

5. The circuit of claim 1, wherein, to generate the switching speed signal, the switching speed controller is configured to:
determine, based on the overstress signal, whether to increase or decrease the switching speed;
determine the modified switching speed based on the switching speed and the determination of whether to increase or decrease the switching speed; and
generate the switching speed signal to indicate the modified switching speed.

6. The circuit of claim 1,
wherein the switching speed controller comprises a data register configured to store at least first data and second data; and
wherein, to generate the switching speed signal, the switching speed controller is configured to generate the switching speed signal to indicate the first data in response to the overstress signal indicating that the electrical characteristic at the switching element satisfies the threshold value and to indicate the second data in response to the overstress signal indicating that the electrical characteristic at the switching element does not satisfy the threshold value.

7. The circuit of claim 1, wherein the buffer circuitry comprises a comparator configured to compare the device stress signal to a reference signal and to output the overstress signal.

8. The circuit of claim 1, wherein the buffer circuitry comprises an analog-to-digital converter configured to:
generate a plurality of digital values based on the device stress signal; and
generate the overstress signal to indicate a representative digital value for the plurality of digital values.

9. The circuit of claim 1, wherein the device stress detector comprises:
a capacitor configured to store a voltage at the switching element while the switching element is controlled at the switching speed; and
voltage divider circuitry configured to generate the device stress signal from the voltage stored at the capacitor.

10. The circuit of claim 9, wherein the voltage divider circuitry comprises one or more of a voltage divider, a capacitor divider, or a voltage buffer.

11. The circuit of claim 1, wherein the device stress detector, the driver circuitry, and the switching speed controller are formed on a single semiconductor circuit, the single semiconductor circuit comprising a printed circuit board, an integrated circuit package, or a semiconductor die.

12. The circuit of claim 11, wherein the switching element is formed on the single semiconductor circuit.

13. The circuit of claim 1,
wherein the device stress detector and driver circuitry are formed on a first semiconductor circuit, the first semiconductor circuit comprising a printed circuit board, an integrated circuit package, or a die; and
wherein the switching speed controller is formed on a second semiconductor circuit.

14. The circuit of claim 1, wherein the power converter circuitry comprises one or more of an DC/DC converter, an AC/DC converter, an DC/AC converter, an AC/AC converter, an inverter, a multi-phase inverter, a flyback converter, a switched-mode power supply, a switching current source, a class-D amplifier, a motor driver, a half-bridge, a full bridge, or a light emitting diode driver.

15. The circuit of claim 1, wherein the electrical characteristic at the switching element comprises a voltage or a current.

16. A system comprising:
driver circuitry configured to control a switching element of power converter circuitry at a switching speed;
a device stress detector configured to generate a device stress signal indicating an electrical characteristic at the switching element while the driver circuitry controls the switching element at the switching speed;
buffer circuitry configured to generate, based on the device stress signal, an overstress signal indicating whether the electrical characteristic at the switching element satisfies a threshold value; and
a switching speed controller configured to generate, based on the overstress signal, a switching speed signal indicating a change to the switching speed and output the switching speed signal to driver circuitry,
wherein the driver circuitry is further configured to control, based on the switching speed signal, the switching element at a modified switching speed.

17. The system of claim 16, wherein the electrical characteristic comprises a voltage at the switching element and wherein, to generate the switching speed signal, the switching speed controller is configured to:
generate the switching speed signal to indicate increasing the switching speed in response to the overstress signal indicating that a peak voltage at the switching element is less than the threshold value; and
generate the switching speed signal to indicate decreasing the switching speed in response to the overstress signal indicating that the peak voltage at the switching element is greater than the threshold value.

18. The system of claim 17,
wherein the switching speed comprises one or more of a rising slope value of a pulse modulated signal controlling the switching element or a falling slope value of the pulse modulated signal controlling the switching element, and
wherein to control the switching element at the modified switching speed the driver circuit is configured to modify a control node current or a control node voltage applied to the switching element.

19. The system of claim 16, wherein, to generate the switching speed signal, the switching speed controller is further configured to generate the switching speed signal to indicate whether to increase or decrease the switching speed.

20. A method comprising:
generating a device stress signal indicating an electrical characteristic at a switching element of power converter circuitry while driver circuitry controls the switching element at a switching speed;
generating, based on the device stress signal, an overstress signal indicating whether the electrical characteristic at the switching element satisfies a threshold value;
generating, based on the overstress signal, a switching speed signal indicating a change to the switching speed; and
outputting the switching speed signal to the driver circuitry, wherein the driver circuitry is configured to control, based on the switching speed signal, the switching element at a modified switching speed.
